(19) United States
(12) Patent Application Publication
(10) Pub. No.: US 2012/0167971 A1
(43) Pub. Date: Jul. 5, 2012

(54) Textured coating for thin-film solar cells and/or methods of making the same

(76) Inventors: Alexey Krasnov, Canton, MI (US); Maximo Frati, Ann Arbor, MI (US)

(21) Appl. No.: 13/064,622

(22) Filed: Apr. 4, 2011

Related U.S. Application Data
(63) Continuation-in-part of application No. 12/929,111, filed on Dec. 30, 2010.

(51) Int. Cl. H01L 31/0224; H01L 31/18

(52) U.S. Cl. 136/256; 438/71; 257/E31.126

(57) ABSTRACT

Certain example embodiments of this invention relate to a front electrode for solar cell devices (e.g., amorphous silicon or a-Si solar cell devices), and/or methods of making the same. Advantageously, certain example embodiments include a front contact including a transparent conductive oxide layer of aluminum-doped zinc oxide. In certain example embodiments, the AZO-based layer is ion beam treated post-deposition in order to increase its surface energy and/or decrease its contact layer so as to make the layer less hydrophobic. In certain example embodiments, after ion beam treatment, a weak acid may be used to texture the layer of AZO. The reduced contact angle of the layer of AZO may improve its ability to be textured. A semiconductor may be provided over the textured layer of AZO. In certain example embodiments, the textured, ion beam-treated AZO may result in an improved front contact.

This application is a continuation-in-part (CIP) of U.S. application Ser. No. 12/929,111, filed Dec. 30, 2010, the disclosure of which is hereby incorporated by reference.

### FIELD OF THE INVENTION

Certain example embodiments of this invention relate to solar cell devices, and/or methods of making the same. More particularly, certain example embodiments relate to a front transparent conductive electrode for solar cell devices (e.g., amorphous silicon or a-Si solar cell devices), and/or methods of making the same. Certain example embodiments relate to ion beam treated textured transparent conductive oxide (TCO)-based layers in transparent conductive coatings (TCCs). Using an ion beam to treat a TCO-based layer prior to it being textured by etching may permit the contact angle of the TCO-based layer to be advantageously lowered prior to application of any etchants. By lowering the contact angle in this manner, the materials used to etch the TCO-based layer may be applied more evenly in some example instances. In certain example embodiments, this advantageously may improve the uniformity of the coverage and/or distribution of the etchant over the TCO-based layer, which may result in a more uniformly textured TCO-based layer.

### BACKGROUND AND SUMMARY OF EXAMPLE EMBODIMENTS OF THE INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front electrode or contact. Typically, the transparent front electrode is made of a pyrolytic transparent conductive oxide (TCO) such as zinc oxide or tin oxide formed on a substrate such as a glass substrate. In many instances, the transparent front electrode is formed of a single layer using a method of chemical pyrolysis where precursors are sprayed onto the glass substrate at approximately 400 to 600 degrees C. Typical pyrolitic fluorine-doped tin oxide TCOs as front electrodes may be about 1000 nm thick, which provides for a sheet resistance (Rs) of about 15 ohms/square. To achieve high output power, a front electrode having a low sheet resistance and good ohm-contact to the cell top layer, and allowing maximum solar energy in certain desirable ranges into the absorbing semiconductor film, are desired.

Unfortunately, photovoltaic devices (e.g., solar cells) with only such conventional TCO front electrodes suffer from various problems.

First, a pyrolitic fluorine-doped tin oxide TCO about 1000 nm thick as the entire front electrode has a sheet resistance (Rs) of about 15 ohms/square which is rather high for the entire front electrode. A lower sheet resistance (and thus better conductivity) would be desired for the front electrode of a photovoltaic device. A lower sheet resistance may be achieved by increasing the thickness of such a TCO, but this will cause transmission of light through the TCO to drop thereby reducing output power of the photovoltaic device.

Second, conventional TCO front electrodes including, for example, pyrolytic tin oxide, allow a significant amount of infrared (IR) radiation to pass therethrough thereby allowing it to reach the semiconductor or absorbing layer(s) of the photovoltaic device. This IR radiation may cause heat, which may increase the operating temperature of the photovoltaic device and thereby reduce the output power thereof.

Third, conventional TCO front electrodes such as pyrolytic tin oxide tend to reflect a significant amount of light in the region of from about 450-700 nm so that less than about 80% of useful solar energy reaches the semiconductor absorbing layer; this significant reflection of visible light is a waste of energy and leads to reduced photovoltaic module output power. Due to the TCO absorption and reflections of light which occur between the TCO (refractive index n about 1.8 to 2.0 at 550 nm) and the thin film semiconductor (n about 3.0 to 4.5), and between the TCO and the glass substrate (n about 1.5), the TCO coated glass at the front of the photovoltaic device typically allows less than 80% of the useful solar energy impinging upon the device to reach the semiconductor film which converts the light into electric energy.

Fourth, the rather high total thickness (e.g., 400 nm) of the front electrode in the case of a 1000 nm thick tin oxide TCO, leads to high fabrication costs.

Fifth, the process window for forming a zinc oxide or tin oxide TCO for a front electrode is both small and important. In this respect, even small changes in the process window can adversely affect conductivity of the TCO. When the TCO is the sole conductive layer of the front electrode, such adverse affects can be detrimental.

Further, the efficiency of a solar cell may be increased by texturing the TCO. However, this is often done by etching. In certain example instances, etching may be detrimental to the overall solar cell, e.g., in the event that areas are over-etched. In further example instances, it may be difficult to evenly distribute the etchant(s) over the layer that is to be textured.

Thus, it will be appreciated that there is a need in the art for improved solar cell devices, and/or methods of making the same.

One aspect of certain example embodiments of this invention relates to a method of making a front electrode superstrate for a solar cell, the method comprising: sputter-depositing a transparent conductive oxide coating comprising a layer comprising aluminum-doped zinc oxide (AZO) over a glass substrate; ion beam treating the layer comprising AZO with at least one ion beam and at least one ion source in order to reduce a contact angle of the layer comprising AZO; etching the layer comprising AZO with a weak acid in order to texture a surface of the layer comprising AZO; and forming a semiconductor layer on the layer of AZO in making the front electrode superstrate.

Another aspect of certain embodiments of this invention relates to a method of making a front contact for a solar cell, the method comprising: depositing a layer comprising a transparent conductive oxide (TCO) on a glass substrate; ion beam treating the layer comprising the TCO with at least one ion source to reduce the contact angle of the layer comprising the TCO by at least about 10 degrees; and etching the layer comprising a TCO with a weak acid in order to texture at least a surface of the TCO.

Still further example embodiments relate to a front electrode for use in a photovoltaic device, the electrode comprising a sputter-deposited and ion beam-treated transparent conductive oxide layer comprising aluminum-doped zinc oxide (AZO), wherein the layer comprising AZO has a contact angle of no greater than about 65 degrees.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a cross-sectional view of an example photovoltaic device according to certain example embodiments of this invention;

FIG. 2 is an example XRD graph showing AZO with and without an ITO underlayer;

FIG. 3 is a first example layer stack for producing high haze in connection with a textured stoichiometric AZO layer deposited on an ITO layer in accordance with an example embodiment of this invention;

FIG. 4 is a second example layer stack for producing high haze in connection with a textured stoichiometric AZO layer deposited on an ITO layer in accordance with an example embodiment of this invention;

FIG. 5 is a third example layer stack for producing high haze in connection with a textured stoichiometric AZO layer deposited on an ITO layer in accordance with an example embodiment of this invention;

FIG. 6 is cross-sectional view of an AZO-based layer in a solar cell that has been over-etched;

FIG. 7 is cross-sectional view of a semiconductor layer being in direct contact with a metallic, conductive layer due to over-etching;

FIG. 8 is a first example layer stack for reducing the possibility of over-etching with a textured stoichiometric AZO layer deposited on an ITO layer in accordance with an example embodiment of this invention;

FIG. 9 is a flowchart showing an exemplary method according to certain example embodiments of the invention;

FIG. 10 is a cross-sectional view of a solar cell according to certain example embodiments of the invention;

FIGS. 11(a) and 11(b) respectively show cross-sectional views of a naturally textured, pyrolytically-deposited tin oxide layer and a textured aluminum-doped zinc oxide layer;

FIG. 12 is a cross-sectional view of a TCO-based layer being ion beam treated;

FIGS. 13(a)-(d) are side views of a layer comprising aluminum-doped zinc oxide with a sessile drop of water thereon, where FIGS. 13(a) and 13(c) show the contact angle of sputtered aluminum-doped zinc oxide as-deposited, and FIGS. 13(b) and 13(d) show the contact angle of a sputter-deposited layer of aluminum-doped zinc oxide after the layer has been ion beam treated;

FIGS. 14(a) and 14(b) respectively show scanning electron microscope (SEM) micrographs of as-deposited aluminum-doped zinc oxide, and ion beam treated aluminum-doped zinc oxide; and

FIGS. 15(a) and 15(b) are SEM micrographs of the surface of an aluminum-doped zinc oxide-based layer after etching, where FIG. 15(a) shows a surface that was etched without pre-treatment with an ion beam(s), and where FIG. 15(b) shows the surface of a layer that was etched after being treated with an ion beam.

### DETAILED DESCRIPTION OF EXAMPLE EMBODIMENTS OF THE INVENTION

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, single or tandem thin-film solar cells, CdS and/or CdTe (including CdS/CdTe) photovoltaic devices, polysilicon and/or microcrystalline Si photovoltaic devices, and the like.

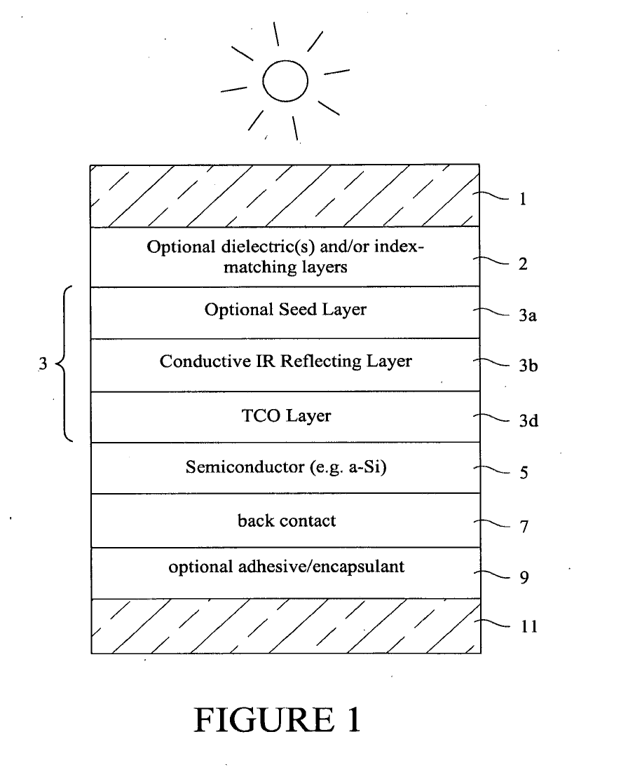

FIG. 1 is a cross sectional view of a photovoltaic device according to an example embodiment of this invention. The photovoltaic device includes transparent front glass substrate 1 (other suitable material may also be used for the substrate instead of glass in certain instances), optional dielectric layer(s) 2, multilayer front electrode 3, active semiconductor film 5 of or including one or more semiconductor layers (such as pin, pn, pinpin tandem layer stacks, or the like), back electrode/contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may also be provided in the device. Front glass substrate 1 and/or rear superstrate (substrate) 11 may be made of soda-lime-silica based glass in certain example embodiments of this invention; and it may have low iron content and/or an antireflection coating thereon to optimize transmission in certain example instances. While substrates 1, 11 may be of glass in certain example embodiments of this invention, other materials such as quartz, plastics or the like may instead be used for substrate(s) 1 and/or 11. Moreover, superstrate 11 is optional in certain instances. Glass 1 and/or 11 may or may not be thermally tempered and/or patterned in certain example embodiments of this invention. Additionally, it will be appreciated that the word “on” as used herein covers both a layer being directly on and indirectly on something, with other layers possibly being located therebetween.

Dielectric layer(s) 2 may be of any substantially transparent material such as a metal oxide and/or nitride which has a refractive index of from about 1.5 to 2.5, more preferably from about 1.6 to 2.5, more preferably from about 1.6 to 2.2, more preferably from about 1.6 to 2.0, and most preferably from about 1.6 to 1.8. However, in certain situations, the dielectric layer 2 may have a refractive index (n) of from about 2.3 to 2.5. Example materials for dielectric layer 2 include silicon oxide, silicon nitride, silicon oxynitride, zinc oxide, tin oxide, titanium oxide (e.g., TiO₂), aluminum oxynitride, aluminum oxide, or mixtures thereof. Dielectric layer(s) 2 functions as a barrier layer in certain example embodiments of this invention, to reduce materials such as sodium from migrating outwardly from the glass substrate 1 and reaching the IR reflecting layer(s) and/or semiconductor. Moreover, dielectric layer 2 is material having a refractive index (n) in the range discussed above, in order to reduce visible light reflection and thus increase transmission of visible light (e.g., light from about 450-700 nm and/or 450-600 nm) through the coating and into the semiconductor 5 which leads to increased photovoltaic module output power.

Still referring to FIG. 1, multilayer front electrode 3 in the example embodiment shown in FIG. 1, which is provided for purposes of example only and is not intended to be limiting, includes from the glass substrate 1 outwardly a first optional seed layer 3a, conductive, substantially metallic, substantially transparent IR reflecting layer 3b, transparent conductive oxide layer 3d, and optional buffer layer 3f. Layer 3a is optional and may be a dielectric layer and/or may serve as a seed layer for the layer 3b. In certain example embodiments, however, layer 3a may be part of the dielectric/optically-matching layer(s) 2. This multilayer film 3 makes up the front electrode in certain example embodiments of this invention. Of course, it is possible for certain layers of electrode 3 to be removed in certain alternative embodiments of this invention, and it is also possible for additional layers to be provided in the multilayer electrode 3. Front electrode 3 may be continuous across all or a substantial portion of glass substrate 1, or alternatively may be patterned into a desired design (e.g., stripes), in different example embodiments of this invention. Each of layers/films 1-3 is substantially transparent in certain example embodiments of this invention.

Conductive substantially metallic IR reflecting layer 3b may be of or based on any suitable IR reflecting material such as silver, gold, or the like. These materials reflect significant amounts of IR radiation, thereby reducing the amount of IR which reaches the semiconductor film 5. Since IR increases the temperature of the device, the reduction of the amount of IR radiation reaching the semiconductor film 5 is advantageous in that it reduces the operating temperature of the photovoltaic module so as to increase module output power. Moreover, the highly conductive nature of substantially metallic layer 3b permits the conductivity of the overall electrode 3 to be increased. In certain example embodiments of this invention, the multilayer electrode 3 has a sheet resistance of less than or equal to about 12 ohms/square, more preferably less than or equal to about 9 ohms/square, and even more preferably less than or equal to about 6 ohms/square. Again, the increased conductivity (same as reduced sheet resistance) increases the overall photovoltaic module output power, by reducing resistive losses in the lateral direction in which current flows to be collected at the edge of cell segments. It is noted that conductive substantially metallic IR reflecting layer 3b (as well as the other layers of the electrode 3) is thin enough so as to be substantially transparent to visible light. In certain example embodiments of this invention, conductive substantially metallic IR reflecting layer 3b may be from about 3 to 18 nm thick, more preferably from about 5 to 12 nm thick, and most preferably from about 6 to 11 nm thick in certain example embodiments of this invention. These thicknesses are desirable in that they permit the layer 3b to reflect significant amounts of IR radiation, while at the same time being substantially transparent to visible radiation which is permitted to reach the semiconductor 5 to be transformed by the photovoltaic device into electrical energy. The highly conductive IR reflecting layer 3b attribute to the overall conductivity of the electrode 3 much more than the TCO layers; this allows for expansion of the process window(s) of the TCO layer(s) which has a limited window area to achieve both high conductivity and transparency.

TCO layer 3d may be of any suitable TCO material including but not limited to conducive forms of zinc oxide, zinc aluminum oxide, tin oxide, indium-tin-oxide, indium zinc oxide (which may or may not be doped with silver), or the like. These layers are typically substoichiometric so as to render them conductive as is known in the art. For example, these layers are made of material(s) which gives them a resistance of no more than about 10 ohm-cm (more preferably no more than about 1 ohm-cm, and most preferably no more than about 20 mohm-cm). One or more of these layers may be doped with other materials such as fluorine, aluminum, antimony or the like in certain example instances, so long as they remain conductive and substantially transparent to visible light. In certain example embodiments of this invention, TCO layer 3d is from about 3 to 80 nm thick, more preferably from about 5-30 nm thick, with an example thickness being about 10 nm. Optional layer 3a is provided mainly as a seeding layer for layer 3b and/or for antireflection purposes, and its conductivity is not as important as that of layers 3b-3e (thus, layer 3a may be a dielectric in certain example embodiments). In other example embodiments of this invention, TCO layer 3d is from about 20 to 150 nm thick, more preferably from about 40 to 120 nm thick, with an example thickness being about 74-75 nm. In still further example embodiments of this invention, TCO layer 3d is from about 20 to 180 nm thick, more preferably from about 40 to 130 nm thick, with an example thickness being about 94 or 115 nm. In certain example embodiments, part of layer 3d, e.g., from about 1-25 nm or 5-25 nm thick portion, at the interface between layers 3d and 5 may be replaced with a low conductivity high refractive index (n) film 3f such as titanium oxide to enhance transmission of light as well as to reduce back diffusion of generated electrical carriers; in this way performance may be further improved. In certain example embodiments, more than one of each of substantially metallic layer 3b and TCO-based layer 3d may be included in the front electrode of a photovoltaic device, in an alternating fashion (e.g., 3b/3d/3b/3d etc.).

In certain example embodiments of this invention, the photovoltaic device may be made by providing glass substrate 1, and then depositing (e.g., via sputtering or any other suitable technique) an optional dielectric and/or index-matching layer and/or coating on the glass substrate. Then, multilayer electrode 3 is deposited on the substrate 1. Thereafter the structure including substrate 1 and front electrode 3 is coupled with the rest of the device in order to form the photovoltaic device shown in FIG. 1. For example, the semiconductor layer 5 may then be formed over the front electrode on substrate 1. Alternatively, the back contact 7 and semiconductor 5 may be fabricated/formed on substrate 11 (e.g., of glass or other suitable material) first; then the electrode 3 and dielectric 2 may be formed on semiconductor 5 and encapsulated by the substrate 1 via an adhesive such as EVA.

In certain example embodiments, when TCO layer(s) and conductive substantially metallic IR reflecting layers are alternated, the alternating nature of the TCO layers 3d and the conductive substantially metallic IR reflecting layers 3b, is also advantageous in that it also one, two, three, four or all of the following advantages to be realized: (a) reduced sheet resistance (Rs) of the overall electrode 3 and thus increased conductivity and improved overall photovoltaic module output power; (b) increased reflection of infrared (IR) radiation by the electrode 3 thereby reducing the operating temperature of the semiconductor 5 portion of the photovoltaic module so as to increase module output power; (c) reduced reflection and increased transmission of light in the visible region of from about 450-700 nm (and/or 450-600 nm) by the front electrode 3 which leads to increased photovoltaic module output power; (d) reduced total thickness of the front electrode coating 3 which can reduce fabrication costs and/or time; and/or (e) an improved or enlarged process window in forming the TCO layer(s) because of the reduced impact of the TCO's conductivity on the overall electric properties of the module given the presence of the highly conductive substantially metallic layer(s).

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe may also be used for semiconductor film 5 in alternative embodiments of this invention.

Back contact, reflector and/or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA or PVB. However, other materials such as Tedlar type plastic, Nuvasil type plastic, Tefzel type plastic or the like may instead be used for layer 9 in different instances.

Given the structure identified above, certain example embodiments relate to a front transparent conductive electrode for solar cell devices (e.g., amorphous silicon or a-Si solar cell devices), and/or methods of making the same. Certain example embodiments enable advantageously enable high haze to be realized in the top layer of the thin film stack.

The front transparent contact of a typical superstrate thin film amorphous silicon (a-Si) solar cell includes a glass base supporting a transparent conductive film. As indicated above, this transparent conductive film typically includes pyrolytically deposited fluorine-doped tin oxide (SnO₂:F). The efficiency of a-Si modules sometimes may be increased by 20% via surface texturing of the transparent conductor on which the a-Si semiconductor is deposited for the effective light scattering into the semiconductor layer of the device. The pyrolytically deposited SnO₂:F typically is “naturally” textured during its deposition.

Sputter-deposited aluminum-doped zinc oxide (AZO) may be used as an alternative to pyrolytically deposited SnO₂:F. The AZO may be chemically etched following its deposition. The etching process may create sufficient roughness of the AZO surface to produce the needed light scattering. Unfortunately, however, the chemical etching often results in a substantial thickness loss of the AZO layer. This generally requires depositing a relatively thick (e.g., about 1 micron thick) sputter-deposited AZO layer to provide a sufficiently low sheet resistance. As will be appreciated, the low sheet resistance of the transparent contact is needed for the effective extraction of electrical charges generated in the device.

An alternative technique for achieving a sufficient lateral conductivity of the textured transparent contact is to deposit an additional highly conductive transparent layer such as, for example, indium tin oxide (ITO), below the AZO. In such a case, the AZO deposited on the ITO film may be made substantially thinner. This technique may offer certain advantages over a single layer AZO design, e.g., when the deposition (of some or all layers) is performed without intentional heating of the substrate (and/or the layers thereon). In other words, this technique may offer certain advantages over a single layer AZO design when the deposition is performed approximately at room temperature, thereby resulting in RT-AZO. The stack may require post-deposition baking (e.g., at about 300-500 degrees C.) to reduce optical absorption and electrical resistivity of the transparent electrode.

To achieve the desired optical and electrical performance of sputtered RT-AZO, the use of near-stoichiometric ceramic AZO targets may be desirable. For example, using close-to-stoichiometric ceramic AZO targets may make it easier to optimize the composition of the RT-AZO deposit film by incorporating oxygen during the post-deposition baking. One disadvantage of using stoichiometric targets for the AZO deposition on ITO is that the crystalline ITO has a tendency to inhibit haze in stoichiometric AZO during texturing. This also applies to high-temperature AZO (HT-AZO) deposited on the ITO layer.

One reason that the ITO layer affects haze development in AZO relates to the fact that the ability of the AZO layer to produce haze depends on the ratio of strain in the film in the directions parallel and perpendicular to its growth axis. In AZO deposited on an amorphous substrate, this ratio is sufficient to result in a high haze. The presence of the crystalline ITO layer, however, affects the crystallinity of the AZO and results in the reduced strain ratio. This, in turn, results in a reduced difference of the etch rate in the two orthogonal directions of the crystalline AZO and, ultimately, in a low haze.

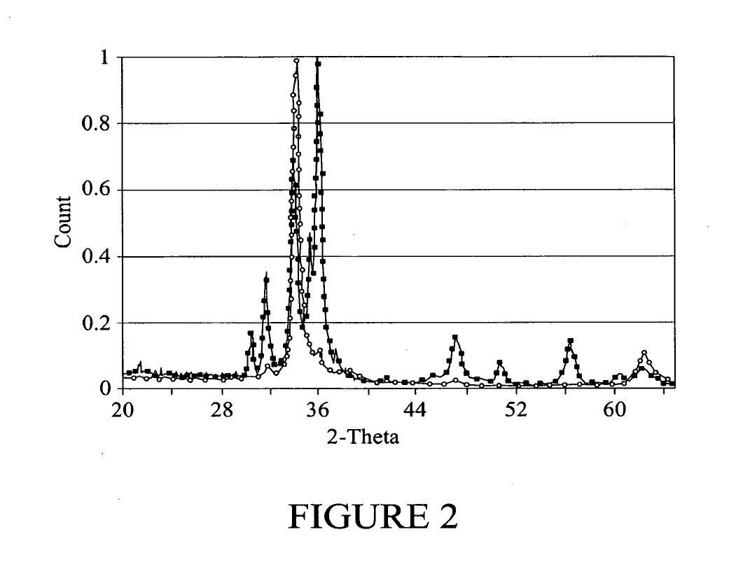

FIG. 2 is an example XRD graph showing AZO with (solid squares) and without (hollow circles) an ITO underlayer.

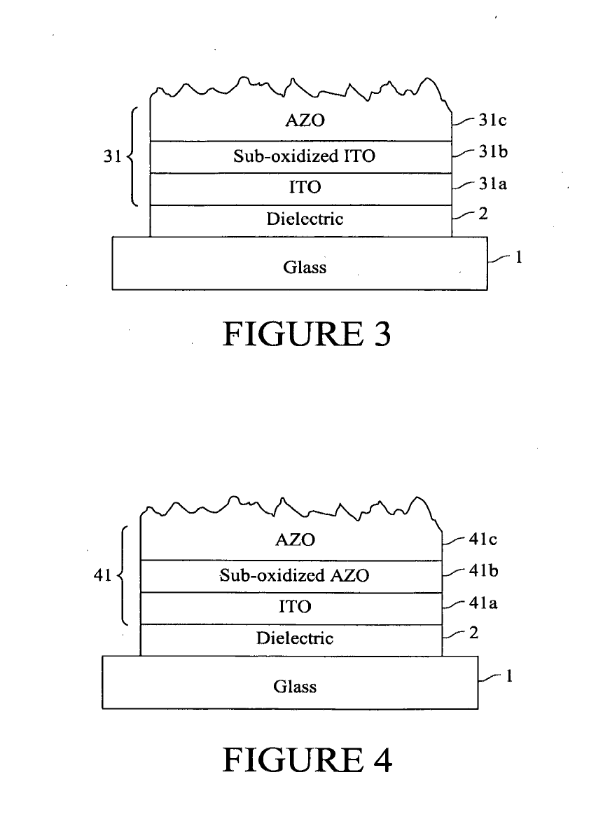

Certain example embodiments therefore relate to techniques that produce high haze in textured stoichiometric AZO deposited on an ITO film. This may be accomplished using one or more of the following and/or other example techniques. The resulting layer stacks are shown in FIGS. 3-5 (described in greater detail below). In brief, FIGS. 3-5 each show approaches for producing high haze in connection with a textured stoichiometric AZO layer deposited (directly or indirectly) on an ITO layer in accordance with example embodiments of this invention.

First, a substantially sub-oxidized AZO layer may be provided between the ITO layer and the stoichiometric AZO layer. This example technique may result in an “amorphozation” of the lower portion of the AZO layer and/or the upper portion of the ITO layer. This tends to reduce (and sometimes even cancel out) the effect of the crystalline ITO on the AZO layer.

This first illustrative arrangement is shown, for example, in FIG. 3. The FIG. 3 example embodiment includes a glass substrate 1, which supports a dielectric layer 2 and a multilayer transparent conductive coating (TCC) 31. The underlying dielectric layer 2 supports the TCC 31, which may comprise (in order moving away from the dielectric layer 2), an ITO layer 31a, a sub-oxidized ITO layer 31b, and a layer of textured AZO 31c. The ITO layer 31a and/or the AZO 31c may be stoichiometric or substantially stoichiometric in different embodiments of this invention. It will be appreciated that the sub-oxidized ITO layer 31b will contain less oxygen than the “main” ITO layer 31a. In certain example embodiments, the “main” ITO layer 31a also may be sub-oxidized. However, even in embodiments where the “main” ITO layer 31a is sub-oxidized, the sub-oxidized ITO layer 31b still will contain less oxygen than the “main” ITO layer 31a. In certain example embodiments, the sub-oxidized ITO layer 31b preferably has an absorption of 3-6% per 100 nm of thickness, more preferably 4.5% per 100 nm of thickness. In certain example embodiments, the sub-oxidized ITO layer 31b may have optical constants n and k of 1.9-2.05 and 0.005-0.025, respectively, at 550 nm, and more preferably 1.97 and 0.01, respectively at 550 nm.

In certain example embodiments, the ITO layer 31a and/or the AZO 31c may have a refractive index of about 1.9-2.05 at 550 nm. In certain example embodiments, the ITO layer 31a may be provided at a thickness of 50-500 nm, more preferably 100-300 nm, and still more preferably at about 200 nm. In certain example embodiments, the AZO 31c may be provided at a thickness of 300-1000 nm, more preferably 400-700 nm, and still more preferably at about 500 nm. In certain example embodiments, the sub-oxidized ITO layer 31b may be provided at a thickness of 10-200 nm, more preferably 20-100 nm, and still more preferably at about 40 nm.

A conductive layer of or comprising Ag (not shown in FIG. 3) may be deposited above and/or below the ITO layer 31a in certain example embodiments. This Ag-based layer may be highly conductive and may be deposited to a thickness of 0.5-3 nm, more preferably 0.7-2 nm, and sometimes to about 1 nm.

In certain example embodiments, rather than providing two separate ITO layers 31a and 31b, a single graded ITO layer (not shown) may be provided, such that the oxygen content is higher closer to the dielectric layer 2 and lower closer to the AZO layer 31c. In certain example embodiments, even when separate ITO layers 31a and 31b are provided, one or both of such layers may be graded, e.g., as described above. In certain example embodiments AZO etching may be performed using a 5% acetic acid solution.

The sub-oxidized ITO layer 31b, provided as an insertion layer, may help serve as an etch stop. In general, absent the insertion layer comprising sub-oxidized ITO layer 31b, the crystallinity of the underlying “main” ITO layer 31a will affect the growth of the AZO and reduce haze because it tends to inhibit large peak/valley formation. Similar principles apply when a single, graded ITO layer is provided. In certain example embodiments, the crystallinity of the AZO will be changed, creating an enlarged peak-to-valley distance, e.g., by enabling the AZO to form higher peaks and/or lower valleys. In particular, in certain example embodiments, the 002 peak will shift, causing the etch rate in the horizontal vs. vertical directions change together and, for example, producing deeper valleys.

Second, a substantially sub-oxidized ITO layer may be provided between stoichiometric ITO and AZO layers. Like the first example technique, this second example technique also may result in an “amorphozation” of the lower portion of the AZO layer and/or the upper portion of the ITO layer, which tends to reduce (and sometimes even cancel out) the effect of the crystalline ITO on the AZO layer.

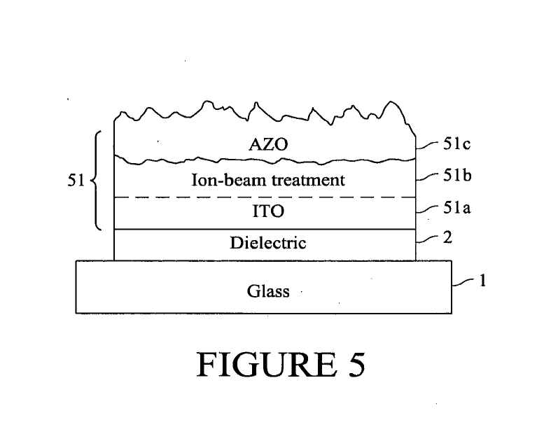

This second illustrative arrangement is shown, for example, in FIG. 4. The FIG. 4 example embodiment is similar to the FIG. 3 example embodiment in that it includes a glass substrate 1, which supports a dielectric layer 2 and a multilayer transparent conductive coating (TCC) 41. The underlying dielectric layer 2 supports the TCC 41, which may comprise (in order moving away from the dielectric layer 2), an ITO layer 41a, a sub-oxidized AZO layer 41b, and a layer of textured AZO 41c. It will be appreciated that the sub-oxidized AZO layer 41b will contain less oxygen than the “main” AZO layer 41c. In certain example embodiments, the “main” AZO layer 41c also may be sub-oxidized. However, even in embodiments where the “main” AZO layer 41c is sub-oxidized, the sub-oxidized AZO layer 41b still will contain less oxygen than the “main” AZO layer 41c.

The sub-oxidized AZO layer 41b in certain example embodiments preferably has an absorption of 2-8% per 100 nm of thickness, and sometimes around 5.3% per 100 nm of thickness. The thickness of the sub-oxidized AZO layer 41b in certain example embodiments is 10-200 nm, more preferably 20-100 nm, and sometimes is preferably about 40 nm. In certain example embodiments, the sub-oxidized AZO layer 41b may have optical constants n and k of 1.93 and 0.008, respectively, at 550 nm.

In certain example embodiments, rather than providing two separate AZO layers 31b and 31c, a single graded AZO layer (not shown) may be provided, such that the oxygen content is higher farther from the substrate 1 and lower closer to the substrate 1. In certain example embodiments, even when separate AZO layers 41b and 41c are provided, one or both of such layers may be graded, e.g., as described above.

Similar to the above, the sub-oxidized AZO layer 31b, provided as an insertion layer, may help serve as an etch stop and may help reduce the effects of the underlying ITO's crystallinity. Also, similar principles apply when a single, graded AZO layer is provided.

In certain example embodiments, an over-oxidized layer may be introduced adjacent to the sub-oxided insertion layer. For instance, in the FIG. 3 example embodiment, an over-oxidized ITO layer may be provided adjacent to the sub-oxided insertion layer 31b. Similarly, in the FIG. 4 example embodiment, an over-oxidized AZO layer may be provided adjacent to the sub-oxided insertion layer 41b. In certain example embodiments, the optional over-oxidized layer may be used as an internal source of oxygen during post-deposition baking. This may help “bake out” the optical absorption of the sub-oxided insertion layer after it has served its role in helping to form the AZO able to provide high haze. The optical absorption of such a layer may be from 1-3% (integrated over 400-700 nm wavelength range, for example) in certain example embodiments. The over-oxided layer may be about 20-100 nm thick, more preferably 40 nm thick, in certain example embodiments. In certain example embodiments, the over-oxided layer may be provided below the sub-oxided insertion layer. A temporary over-oxided layer also may be provided in embodiments where graded layers are used in accordance with certain example embodiments.

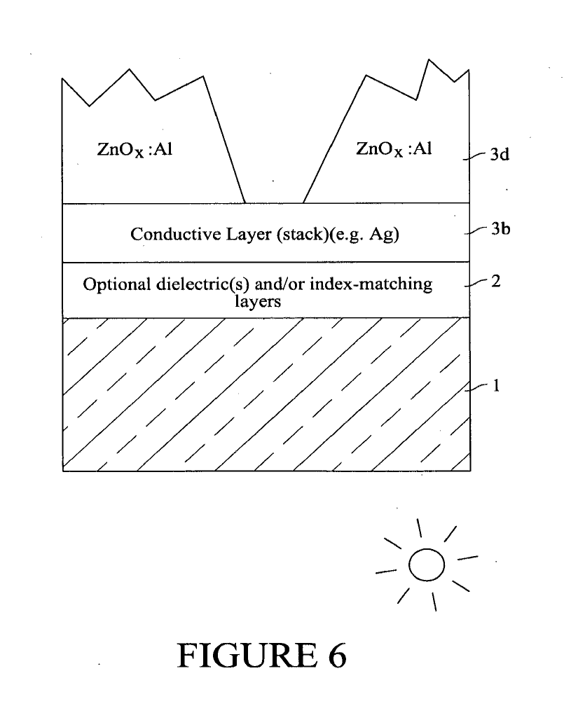

Third, the ITO may be ion-beam treated before providing the top AZO layer. The harsh ion beam treatment of this technique may be used to at least partially erode the upper portion of the ITO so that the AZO layer is not as affected by the ITO crystallinity. This illustrative arrangement is shown, for example, in FIG. 5. The FIG. 5 example embodiment includes a glass substrate 1, which supports a dielectric layer 2 and a multi-layer TCC 51. The multi-layer TCC includes an ITO layer 51a that has been ion-beam treated in the region 51b. The ion-beam treatment in the region 51b affects the crystallinity of at least a portion of the deposited ITO which, in turn, enables the AZO layer 51c to grow and form peaks and valleys as described above.

The ion beam may be implemented at the end of the ITO layer deposition, and the ion beam may use Ar, O₂, and/or any suitable combination of these and/or other gasses. In general, an ion-beam voltage of greater than about 500 V will sufficiently roughen the ITO surface; however a voltage greater than 1000 V is preferred, and a voltage of 3000 V sometimes may be used.

Ion beams, ion sources, ion beam treatments, and the like are disclosed, for example, U.S. Pat. Nos. 6,808,606; 7,030,390; 7,183,559; 7,198,699; 7,229,533; 7,311,975; 7,405,411; 7,488,951; and 7,563,347, and U.S. Publication Nos. 2005/0082493; 2008/0017112; 2008/0199702, the entire contents of each of which is hereby incorporated herein by reference.

In other example embodiments, an alternate method of making a solar cell and/or an alternate structure for the front electrode of a solar cell is/are provided.

In certain example embodiments, it may be desirable to provide a front electrode having only one transparent conductive oxide-based layer and only one conductive, substantially metallic IR reflecting layer. However, if the TCO layer is not rough enough as-deposited, the surface portion (e.g., starting at the surface and extending into the depth of the layer) of the TCO layer may be etched in order to texture its surface therefore increasing the efficiency of the solar cell in certain cases. Etching and/or texturing of the TCO layer is sometimes performed by using a weak acid. However, in certain instances, the TCO layer may not be sufficiently resistant to etching from the weak acid. In certain example embodiments, “weak” spots in the TCO layer may result in random portions of the layer being etched away substantially. In certain cases, the etching of these weak points may be so extensive that the layer under the TCO layer (e.g., the conductive, substantially metallic layer) may be nearly, partially, and/or completely exposed at these certain random points.

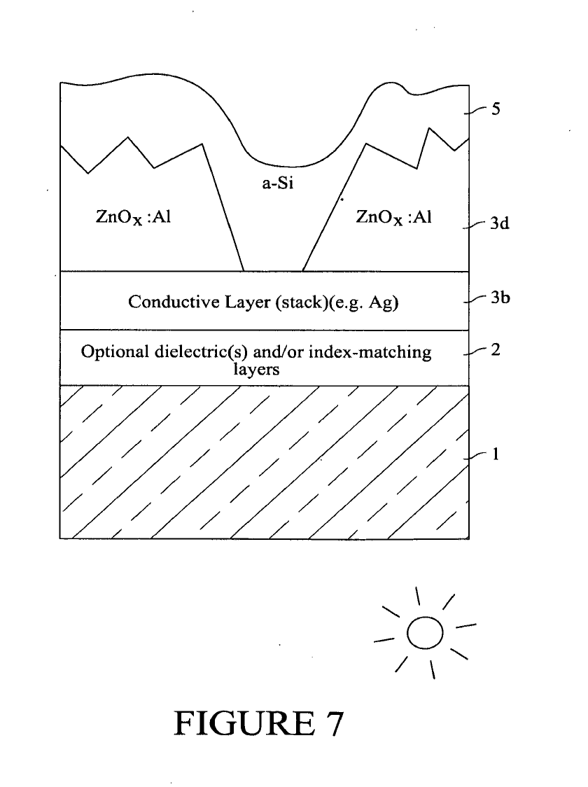

This phenomenon is illustrated in FIG. 6. FIG. 6 is a cross-section view of a portion of a photovoltaic device. FIG. 6 includes substrate 1, upon which (moving outwardly from the substrate) index-matching layer(s) 2, and an electrode comprising a thin, substantially transparent conductive layer and/or layer stack 3b and a transparent conductive oxide layer 3d, are deposited.

In certain other example embodiments, a transparent conductive contact and/or front electrode may comprise a textured Al-doped ZnOx (AZO) top layer (layer 3d) and a thin, substantially transparent conductive under-layer 3b (e.g., a silver-based under-layer). In other example embodiments, conductive layer (stack) 3b may further comprise a NiCrOx “cap” on one or both sides of the thin, substantially transparent conductive layer in order to increase the lateral conductivity (not shown). However, this NiCrOx cap is optional and is only used in some instances on one or both sides of conductive layer 3b.

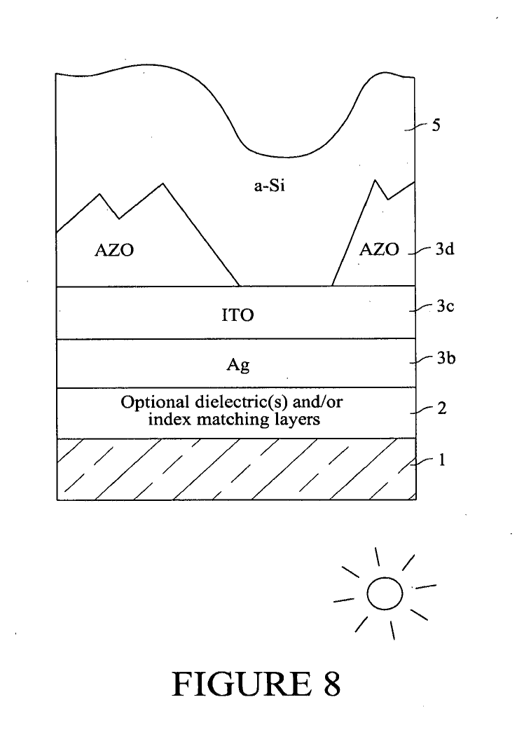

In certain example embodiments, when a TCO-based layer such as AZO is used, the layer may not be sufficiently rough as-deposited, and therefore texturing through the use of a weak acid (e.g., diluted acetic acid, hydrochloric acid, and the like) may be desirable. However, particularly when AZO is used as the TCO layer, the weak spots as described above may be present in the AZO layer. Again, these weak spots may result in over-etching of certain portions of the coating (the points where over-etching may occur may be random in certain embodiments). In certain cases, the over-etching may reach the substantially transparent conductive layer 3b located below the textured TCO 3d. In those cases, when semiconductor 5 is deposited over the textured TCO 3d (as illustrated in FIG. 7), the semiconductor 5 may be in close proximity to and/or direct contact with conductive layer 3b.

Such proximity and/or direct contact between layers 3b and 5, as illustrated in FIG. 7, may be undesirable in that it may result in an abrupt transition from a low refractive index conductive layer (e.g., a layer based on silver) to a high refractive index semiconductor (e.g., Si) in random spots of the coating, in certain cases. Another problem that may arise in certain example embodiments is that an Si-based semiconductor may be in direct electric contact with the highly conductive silver-based (for example) layer. Contacts such as these described herein between layers 3b and 5 may be undesirable in certain example embodiments.

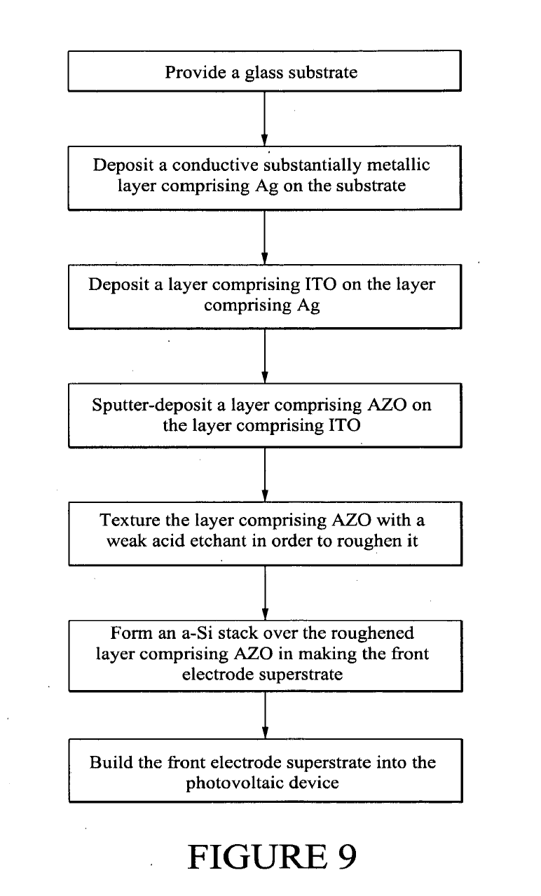

It has advantageously been found that the formation of undesirable contacts between conductive layer 3b and semiconductor 5 through “over-etched” spots of textured TCO layer 3d may be reduced by inserting a thin blocking layer 3c in between conductive layer 3b and TCO layer 3d. This is illustrated in FIG. 8. In certain example embodiments, the blocking layer 3c may comprise any material that is highly conductive and has a poor etchability for many weak acids. For example, in certain exemplary embodiments, blocking layer 3c may be of or include indium tin oxide (ITO). Blocking layer 3c may have a thickness of from about 1 to 300 nm, more preferably from about 2 to 200 nm.

In certain example embodiments, layer 3c advantageously may be of or include a material that is more resistant to etching by weak acids (e.g., 3c should be of a material that has a poor etchability for many weak acids), e.g., as compared to the layer to be roughened 3d by the etchant. Examples of weak acids include, for instance, acetic acid, diluted acetic acid, various concentrations of hydrochloric acid (HCl), and the like. Of course, other acid etchants may be used in different example implementations. In certain instances, the weak acid may be any acid having a pH of from about 1 to 6, more preferably from about 2 to 5, and most preferably from about 2.5 to 4.5.

Further, layer 3c may be conductive and/or highly conductive in certain example embodiments, in order to increase the conductivity and other properties of the overall electrode and/or solar cell. Moreover, in other example embodiments, layers 3b, 3c, and 3d may be repeated at least once (e.g. such that electrode 3 comprises layer 3b/3c/3d/3b/3c/3d.

FIG. 8 also helps illustrate that, through the provision of layer 3c, which is a transparent conductive oxide-based layer that is more resistant to etching by weak acids than is layer 3d in certain example embodiments, a barrier is created (e.g., via blocking layer 3c) between the TCO layer 3d being etched and the substantially transparent conductive layer 3b. In certain example embodiments, layer 3c will reduce (and sometimes even completely prevent) over-etching of TCO layer 3d related to the application of the weak acid. The inclusion of etching-blocking layer 3c between TCO layer 3d and the conductive substantially metallic IR reflecting layer 3b, may sometimes also be considered advantageous in that it can reduce (and sometimes even prevent), direct contact between conductive layer 3b and semiconductor 5. Such contact is undesirable in that it may decrease the efficiency and/or performance of the solar cell due to abrupt changes in refractive index and/or substantially direct electrical contact between the semiconductor and the relatively highly conductive layer 3b (e.g., a silver-based layer). In other example embodiments, where a capping layer is provided above and/or below conductive layer 3b, contact that arises due to over-etching of the TCO-based layer may be between the capping layer and the semiconductor. In certain example embodiments, contact between the semiconductor and the thin capping layer is also disadvantageous.

In certain example embodiments, blocking layer 3c may advantageously be of or include indium tin oxide (e.g., ITO). ITO has sufficient etch-stop properties that render it more resistant to weak acids than AZO. When blocking layer 3c comprises a transparent conductive oxide (such as ITO), the overall conductivity, transmission, and other properties of the electrode may remain substantially unaffected or even improved. Furthermore, when TCO layer 3d comprises AZO, and blocking layer 3c comprises ITO, it may be particularly advantageous because the overall conductivity of the electrode may be improved in some instances.

Although the example design shown in and described in connection with FIG. 8 may not completely eliminate all possibilities for the over-etching of layer 3d (particularly when it is based on ZnOₓ:Al), including a blocking layer 3c that is more resistant to weak acids (e.g., based on ITO) may reduce the risk of, and sometimes even prevent, direct contact with the conductive layer 3b (and/or any capping layers provided above or below conductive layer 3b). In certain example embodiments, it is particularly advantageous for the TCO-based layer 3d to be of or include aluminum-doped zinc oxide, and for blocking layer 3c to be based on ITO. In some instances, ITO and AZO may have similar optical constants. This is advantageous in that there will be sufficient optical separation between the conductive layer 3b and any textured layers (e.g., layer 3d). For instance, in certain example embodiments, the selection of ITO and AZO also may be advantageous in the sense that they may be deposited so as to have closely matching optical constants n and k, preferably within about 15% of one another, more preferably within about 10% of one another, and sometimes within 5% or less of one another. Further, including a layer based on ITO in the front electrode may also increase the overall conductivity of the front electrode and/or front contact.

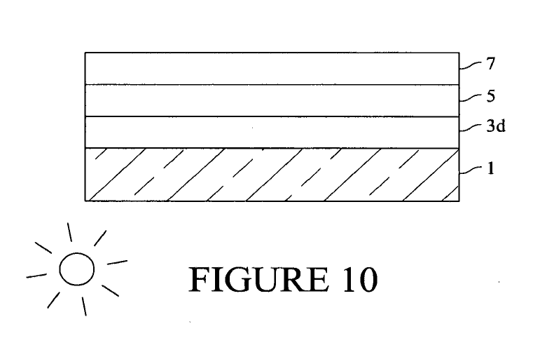

FIG. 9 is a flowchart illustrating an example process for making a textured front contact comprising at least a TCO layer based on AZO deposited over a conductive layer (and/or conductive layer stack), with a blocking layer based on ITO located therebetween in accordance with certain example embodiments of this invention. A glass substrate 1 that serves as the superstrate for the front electrode is provided (step S902). A layer comprising a conductive, substantially metallic material such as silver (3b) is then deposited directly or indirectly on the substrate 1 (step S904). A layer comprising ITO 3c is then deposited directly or indirectly on the layer of silver 3b (step S906). A layer comprising AZO 3d is then sputter-deposited directly or indirectly on the ITO (step S908). This layer comprising AZO 3d is then textured with a weak acid (step S910), e.g., to roughen its surface (potentially improving haze and the overall performance of the photovoltaic device in which the superstrate is to be installed). An a-Si or other suitable semiconductor stack 5 is formed atop the textured layer comprising sputtered AZO 3d (step S912) in making the front electrode superstrate. This front electrode superstrate may then be built into the photovoltaic device (step S914) in certain example embodiments. Although not shown in FIG. 9, additional layers may be provided including, for example, index match or dielectric layers, adhesive layers, sub-oxidized ITO and/or AZO layers, etc.

In certain example embodiments, some or all of the layers may be sputter-deposited. Of course, some or all of the layers may be deposited by other techniques such as, for example, wet-chemical techniques, pyrolytic techniques, CVD, and/or the like.

In certain example embodiments, the dielectric layer(s) 2 may be a single layer or a multi-layer stack. In further example embodiments, layer 2 may be a single or multi-layer stack comprising optical and/or index matching layers. These layers may help to reduce reflection in certain example embodiments. The dielectric layer or dielectric layer stack 2 may be provided directly on the glass substrate. For example, in certain example embodiments, the dielectric layer 2 may comprise titanium oxide, silicon oxide, silicon nitride, silicon oxynitride, zirconium oxide, and/or the like. Indeed, any transparent or partially transparent dielectric layer may be used in different example embodiments of this invention, alone or in a layer stack with the same or different dielectric layers. If a titanium oxide layer is provided, it may in certain example embodiments have a thickness of 0-30 nm, more preferably 5-20 nm, and still more preferably about 7 nm. If a silicon oxynitride layer is provided, it may in certain example embodiments have a refractive index of 1.5-1.9 or, more preferably, of about 1.6. Furthermore, if a silicon oxynitride layer is provided, it may in certain example embodiments have a thickness of 0-80 nm, more preferably 10-50 nm, and still more preferably about 30 nm.

Although certain example embodiments have been described as having a layer of AZO, other transparent conductive coatings may be used in place of or in addition to the AZO. For example, transparent conductive oxide (TCO) coatings such as ITO, indium gallium zinc oxide, indium gallium oxide, indium zinc oxide and/or combinations thereof may be used in place of, or in addition to, the AZO.

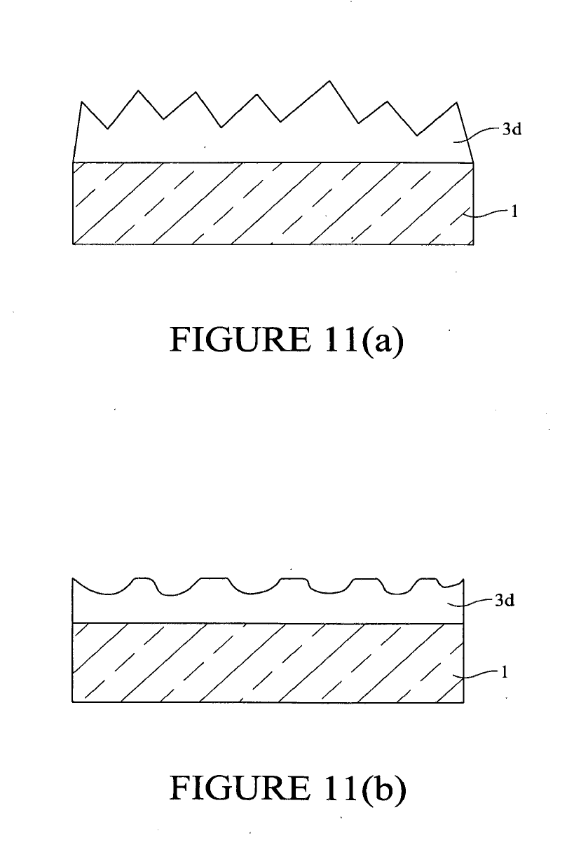

FIG. 10 shows a basic example of a portion of a solar cell comprising a front contact comprising transparent conductive oxide layer and/or coating 3d, semiconductor 5, and back contact layer 7. This transparent conductive oxide coating may be used as a front contact in an amorphous silicon (a-Si) single-junction and/or micro-morph solar cell module(s) in certain example embodiments.

In certain example embodiments, the solar cell of FIG. 10 may be a single-junction thin-film a-Si solar cell. In other example embodiments, the solar cell may be a micro-morph solar cell. In micro-morph a-Si solar cells, an additional microcrystalline Si layer may be added to capture the near infrared portion of the solar spectrum. Although this optional microcrystalline Si layer is not explicitly shown in FIG. 10, it may be added anywhere in the semiconductor 5 region.

In certain example embodiments, layer 3d may be of or include aluminum-doped zinc oxide (AZO). In certain example embodiments, the surface of layer 3d farther from the front glass substrate may be textured in order to improve the photon absorption in the cell, by improving the “coupling-in” of the light transmitted into the cell. Semiconductor 5 may be an amorphous-Si semiconductor comprising “p,” “i,” and “n”-layers in certain example embodiments. In further example embodiments, back contact layer 7 may comprise a metal.

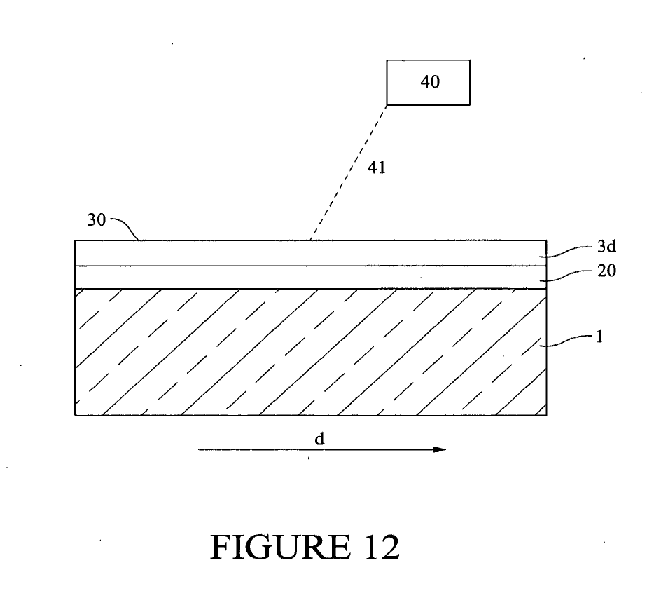

FIG. 11(a) is an illustrative cross-sectional view of “naturally” textured pyrolytically-deposited transparent conductive oxide layer (e.g. SnO2). FIG. 11(b) is an illustrative cross-sectional view of a sputter deposited (and optionally ion beam treated) transparent conductive oxide layer (e.g., including AZO). As can be seen from FIGS. 11(a) and 11(b), AZO-based layers may form a more crater-like textured surface, which in certain example embodiments may advantageously improve the absorption in the solar cell.

In certain example embodiments, the front contact layer 3d comprises a transparent conductive oxide and may be sputter-deposited at room temperature and/or at temperatures higher than room temperature. In other example embodiments, the layer may be deposited via chemical vapor deposition and/or any other suitable method. In certain example embodiments, this TCO-based layer may comprise AZO.

As discussed herein, in certain example embodiments, it may be advantageous to texture the front transparent contact of a typical super/substrate thin film in an a-Si single-junction and/or micro-morph solar cell module(s). The front transparent contact of a typical superstrate thin film a-Si solar cell includes a glass base supporting a transparent conductive film. As indicated above, this transparent conductive film sometimes includes pyrolytically deposited fluorine-doped tin oxide (SnO₂:F). The efficiency of a-Si modules sometimes may be increased by 20% via surface texturing of the transparent conductor on which the a-Si semiconductor is deposited for the effective light scattering into the semiconductor layer of the device. The pyrolytically deposited SnO₂:F typically is “naturally” textured during its deposition.

As discussed herein, sputter-deposited aluminum-doped zinc oxide (AZO) may be used as an alternative to pyrolytically deposited SnO₂:F. However, in certain example embodiments, when AZO is sputter-deposited (or deposited in another manner), the layer may not be sufficiently textured as-deposited. In certain example embodiments, it may be advantageous to texture the layer comprising AZO post-deposition. Therefore, in certain example embodiments, the AZO may be chemically etched following its deposition. The etching process may create sufficient roughness of the AZO surface to produce the needed light scattering.

In certain example embodiments, to texture the sputter-deposited AZO, a mild etchant (e.g., HCl diluted in water, acetic acid, other weak acids and/or bases, stronger acids and/or bases that have been diluted in water, and the like) may be used, which results in crater-shaped features as shown in FIG. 11(b). These crater-shaped features, in certain example embodiments, may have a more favorable shape for effective light scattering than the “natural” texture in pyrolitically deposited tin oxide, e.g. such as what is shown in FIG. 11(a).

In certain example embodiments, the crater-shaped features (e.g., shown in FIG. 11(b), may have a height of from about 50 to 3000 nm (measured from the bottom of the valley to the top of the peak), more preferably from about 100 to 1000 nm, and most preferably from about 500 to 700 nm, with an example, non-limiting “feature” height of about 600 nm.

In order to etch an AZO-based layer, in example embodiments where large lites of coated glass are used, it is desirable that the entire surface be substantially uniformly covered with the etchant. In certain example embodiments, such covering is performed by means of spraying and/or meniscus coating. However, in other instances, the AZO-based layer is covered in etchant(s) by dipping, pouring, misting, sputtering, and/or the like.

Unfortunately, however, in many scenarios (especially where large substrates are used), it may be difficult to apply the etchant to the AZO-based layer such that even, uniform and/or substantially uniform coverage of the whole TCO layer with the etchant(s) is attained. A reason for this may relate to the hydrophobic behavior of AZO-based layers. In certain instances, layers based on AZO may have a low surface energy. This low surface energy may explain the relatively large contact angle and/or hydrophobic behavior of layers based on AZO that results in certain example embodiments.

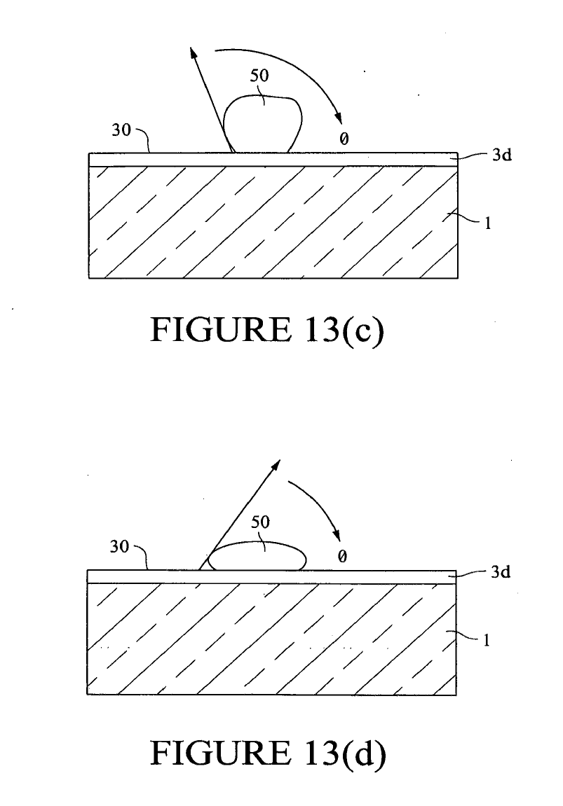

The term “hydrophobic” implies a higher contact angle, as shown in FIGS. 13(a) and 13(c). A hydrophobic surface will repel water and water-based liquids, as well as other liquids, in certain example embodiments. Higher contact angles may result in increasingly hydrophobic (e.g., water-repellant) behavior of a layer.

As is known, the term “contact angle” is indicative of the angle at which a liquid or vapor interface meets a solid surface, in this case, the transparent conductive oxide layer 3d. In certain example embodiments, the liquid or vapor is water and, thus, the “contact angle” relates to the angle at which a liquid or vapor water interface meets the surface of layer 3d. Of course, it will be appreciated that other liquids or vapors could be used in connection with other example embodiments using the techniques described herein.

FIGS. 13(b) and 13(d) illustrate a layer comprising AZO that is less hydrophobic than that shown in FIGS. 13(a) and 13(c) (e.g., more hydrophilic). The layer shown in FIGS. 13(b) and 13(d) is hydrophilic (e.g., it attracts water). As can be seen from FIGS. 13(b) and 13(d), the hydrophilic nature of this layer comprising AZO may help a liquid applied to the surface of the layer spread out more evenly and/or more uniformly. Therefore, increasing the hydrophilicity and/or decreasing the hydrophobicity of a TCO-based layer that is to be textured via etchant(s) would be advantageous in certain example embodiments. One example technique for reducing the contact angle of a layer comprising AZO and/or a TCO-based layer 3d involves treating the surface 30 of layer 3d with an ion beam source(s).

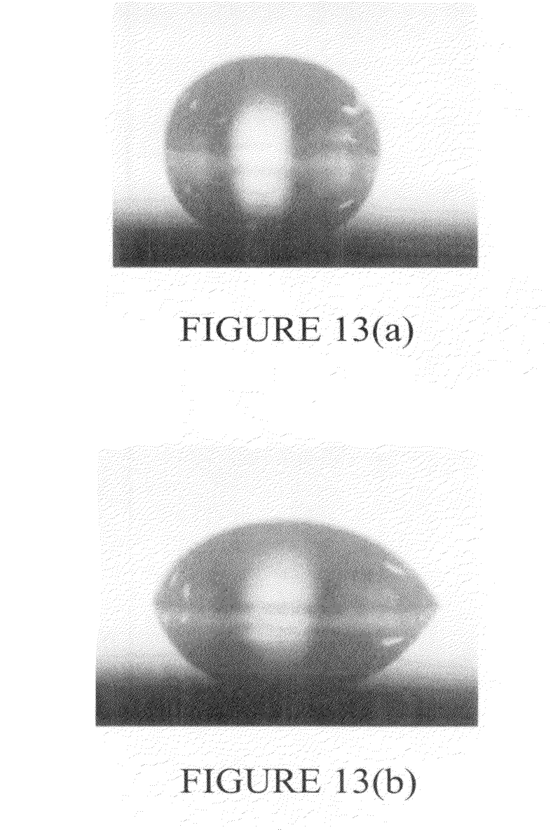

FIG. 12 illustrates an example of ion beam treating layer 3d. Ion source(s) 40 are used to direct an ion beam at substrate 1, with various layers 20 located under layer 3d. In certain example embodiments, the outer surface 30 of the AZO-based layer 3d (e.g., the surface of AZO-based layer 3d farthest from the substrate 1) may be ion beam treated using at least one ion source (and thus at least one ion beam) in order to cause the contact angle θ of the layer 3 to decrease, as shown in FIG. 12. This ion treatment may take place as the coated substrates moves in direction d under one or more ion source(s), or alternatively while the substrate remains still and the ion source(s) move with respect thereto. The ion beam treatment may be performed with one or more of Argon, Oxygen, Nitrogen, Krypton, Xenon, and/or the like. In further example embodiments, other gases may be used instead of or in addition to oxygen in different embodiments of this invention, provided that they cause the contact angle to decrease. This ion beam treatment may be performed in the vacuum area of the coating apparatus, which is at a pressure less than atmospheric (i.e., before the coated article exits via the load lock).

It is noted that the ion beam treatment, while causing the contact angle of layer 3 to decrease, may cause some portion (e.g., 0-20 angstroms) of the layer 3 to be removed during the ion beam treatment process.

Ion beam treatment is described generally in U.S. Pat. Nos. 7,872,422; 7,598,500; 7,563,347; 7,488,951; 7,405,411; 7,229,533; 7,198,699; 7,183,559; 7,030,390; 6,988,463; 6,987,364; 6,878,403; 6,815,690; 6,592,992; 6,303,225; and RE 38,358, the disclosures of which are all herein incorporated by reference. However, it has surprisingly been found that in certain example embodiments, ion beam treatment can be performed on a transparent conductive oxide layer in a solar cell to decrease the contact angle without compromising the optical properties and/or characteristics of the layer and/or the front electrode and/or the solar cell as a whole.

In certain example embodiments, the ion beam may have a voltage of from about 500 to 10,000 V during ion beam treatment of layer 3d, more preferably from about 1,000 to 7,000 V, most preferably from about 4,000 to 6,000 V, with an example, non-limiting voltage of 5,000 V.

Returning to FIG. 13, FIG. 13(a) shows that in certain example embodiments (e.g., such as when an AZO-based layer is sputter-deposited at room temperature), a sputter-deposited layer of AZO may have a contact angle of 88 degrees. In certain example embodiments, the contact angle of a sputter-deposited layer comprising AZO may have a contact angle (as-deposited) of from about 75 to 95 degrees, more particularly 75 to 90 degrees, and specifically from about 80 to 90 degrees. This contact angle is relatively high and may result in hydrophobic behavior of the layer. As can be seen in FIG. 13(a), with this higher contact angle, the AZO-based layer repels the water droplet, and therefore it may be more difficult to uniformly and/or substantially uniformly coat the AZO-based layer with an etchant for texturing in certain examples. In certain example embodiments, if an etchant having water and/or some behavioral properties of water is used, the hydrophobicity of the AZO-based layer may hinder the etching process as explained above.

It has advantageously been found that lowering the contact angle of the AZO-based layer prior to etching may in certain cases improve the uniformity of the coverage of the AZO-based layer with an etchant(s). In certain example embodiments, the contact angle of the AZO-based layer may be lowered by ion beam treating the layer, after it has been deposited, but prior to it being etched. In certain example embodiments, the contact angle of the AZO-based layer may be reduced to from about 40 to 70 degrees, more preferably to from about 50 to 65 degrees, and most preferably to from about 55 to 65 degrees and/or no greater than about 65 degrees. Moreover, in certain example embodiments, the contact angle of the AZO-based layer may be reduced (e.g., due to the post-deposition ion beam treatment) by at least about 10 degrees, more preferably by at least about 15 degrees, even more preferably by at least about 20 degrees, and most preferably by at least about 25 or even 30 or 40 degrees (and all sub-ranges therebetween). In certain example embodiments, however, the layer may be ion beam treated during its deposition.

FIG. 13(b) shows that when an AZO-based layer that has been sputtered at room temperature is ion beam treated, the contact angle can be reduced to about 61 degrees from 88 degrees (e.g., a reduction of 27 degrees). This example is for illustrative purposes only, and ion beam treatment may be performed on any TCO-based layer that is to be textured via etching. The TCO layer that is ion beam treated may be deposited in any manner, and at any temperature.

Thus, it has advantageously been found that ion beam treating the AZO layer prior to texturing will lower the contact angle in such a way that subsequent texturing, e.g., with an acid etchant is improved. More specifically, by lowering the contact angle, the AZO can be better-covered with etchant(s) during etching. This may result in more uniform texturing in certain example embodiments.

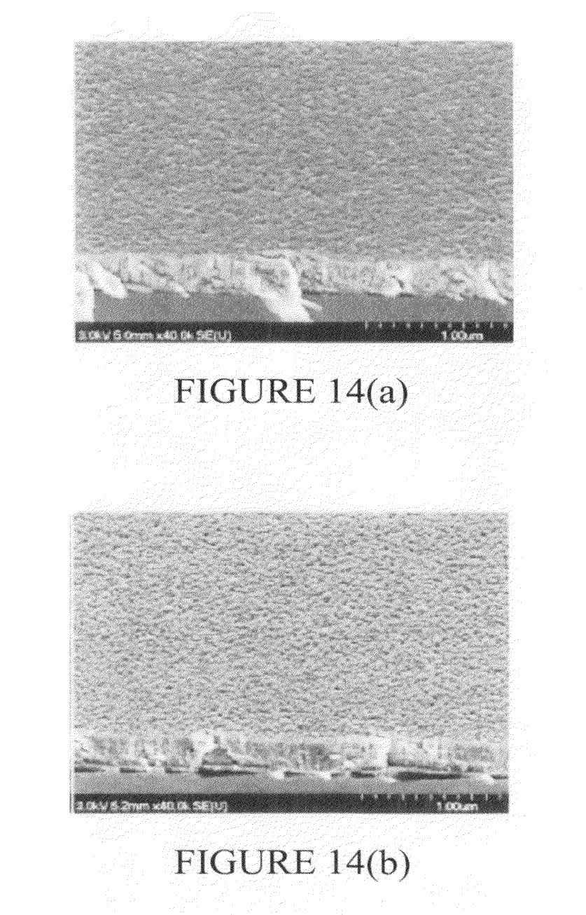

FIGS. 14(a) and 14(b) illustrate this. FIG. 14(a) shows an SEM micrograph of an as-deposited layer comprising AZO. FIG. 14(b) shows an ion-beam treated layer comprising AZO. A rougher texture can be clearly seen in FIG. 14(b) as compared to FIG. 14(a), which may be advantageous for the reasons explained herein.

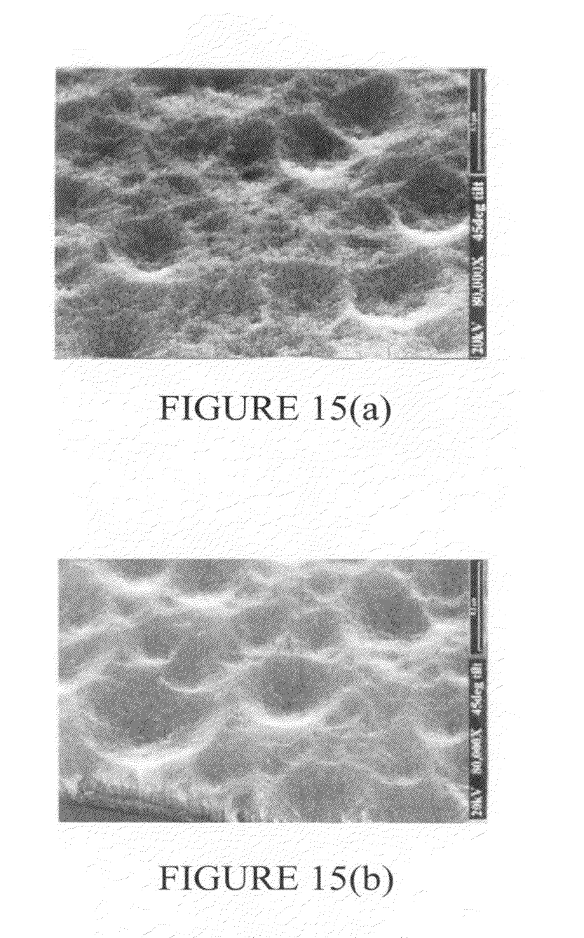

FIGS. 15(a) and 15(b) illustrate a further example advantage of performing ion beam treatment on a layer comprising AZO. In certain example embodiments, treating the AZO-based layer with an ion beam prior to etching may also result in a smoother surface of the craters (described in connection with FIG. 11, for example).

In certain example embodiments, ion beam treatment may be performed on a monolithlic AZO-based coating prior to texturing. The monolithic AZO-based coating may have a post-etch thickness of from about 100 to 1500 nm, more preferably from about 200 to 1000 nm, most preferably from about 600 to 800 nm, with an example, non-limiting thickness being 700 nm.

In further example embodiments, ion beam treatment may be performed on an AZO-based layer that is used as the overcoat in a transparent conductive coating as described herein. In certain example embodiments, the AZO coating may have a post-etch thickness of from about 25 to 800 nm, more preferably from about 50 to 400 nm, and most preferably from about 50 to 250 nm, with a non-limiting example thickness being about 150 nm post-etching. The AZO-based layer may be deposited via sputtering, chemical vapor deposition, and/or any other method as would be understood by one skilled in the art.

In other example embodiments, the AZO may have an aluminum content of from about 0.5 to 10%, more preferably from about 0.5 to 4%, and most preferably from about 1 to 3%, with a non-limiting example being about 2% (Al % by weight). In further examples, the AZO may comprise further dopants, such as one or more of B, F, Ga, and/or the like. The total percentage of dopant in the zinc oxide-based TCO layer when more than one dopant is used may be substantially the same as when only Al is used, or may be higher. In other embodiments, one or more of the B, F, and/or Ga dopants may replace Al in the TCO-based layer entirely.

In certain embodiments, the line speed of the coated glass articles as described herein is from about 0.5 to 15 m/min, more preferably from about 0.5 to 10 m/min, and most preferably from about 2 to 4 m/min, with an example, non-limiting speed being 3 m/min.

In further example embodiments, the post-deposition ion beam treatment alone may create adequate texturing of the layer and/or coating to be used as the front contact for a-Si solar cells.

In certain example embodiments, the AZO layer may have a haze from 5-95%, more preferably at least about 40%.

Any suitable semiconductor may be used in connection with different embodiments of this invention. For example, certain example embodiments may incorporate an a-Si single-junction solar cell, an a-Si tandem-junction solar cell, and/or the like. As alluded to above, the insertion layers and/or the roughening via ion-beam treatment advantageously may help serve as an etch stop, reducing the likelihood that craters produced during etching will go all of the way through the AZO layer and form shorts. The incorporation of the insertion layers and/or the roughening via ion-beam treatment advantageously also may help overcome optical mismatch problems as between the various layers in the overall solar cell.

Although certain example embodiments have been described as having a layer of AZO, other transparent conductive coatings may be used in place of or in addition to the AZO. For example, transparent conductive oxide (TCO) coatings such as ITO, indium gallium zinc oxide, indium gallium oxide, indium zinc oxide and/or combinations thereof may be used in place of, or in addition to, the AZO.

In certain example embodiments, the entire contact assembly (e.g., the entire electrode) may be post-deposition baked and/or heat treated. Such baking and/or heat treating may take place after said ion beam treatment and post-deposition etching of the TCO-based layer, as explained herein, in certain example embodiments. Such baking and/or heat treating in certain example embodiments may be performed at a temperature of 50-550 degrees C., more preferably about 200-300 degrees C., most preferably from about 250 to 290 degrees C., with an example, non-limiting temperature being 270 degrees C. The baking and/or heat treating may be performed in certain example embodiments for 1-60 minutes, more preferably 20-40 minutes, with an example, non-limiting baking time of 30 minutes. Such baking and/or heat treating advantageously may help increase transmission and conductivity, e.g., by making some or all of the layers more crystallized. Baking and/or heat treating may be performed before or after the etching, in different embodiments of this invention.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a front electrode superstrate for a solar cell, the method comprising:
sputter-depositing a transparent conductive oxide coating comprising a layer comprising aluminum-doped zinc oxide (AZO) over a glass substrate;
ion beam treating the layer comprising AZO with at least one ion beam and at least one ion source in order to reduce a contact angle of the layer comprising AZO;
etching the layer comprising AZO with a weak acid in order to texture a surface of the layer comprising AZO; and
forming a semiconductor layer on the layer of AZO in making the front electrode superstrate.

2. The method of claim 1, wherein the semiconductor comprises an amorphous silicon (a-Si) thin film layer stack.

3. The method of claim 2, further comprising depositing at least one conductive, substantially metallic layer on a glass substrate under the layer comprising AZO,
wherein the conductive, substantially metallic layer and the layer comprising AZO together form a transparent conductive coating to be used as a front electrode in a photovoltaic device.

4. The method of claim 3, wherein the conductive, substantially metallic layer is an IR reflecting layer.

5. The method of claim 1, wherein the AZO-based layer is deposited at room temperature.

6. The method of claim 1, wherein the AZO-based layer is deposited at a temperature of no greater than about 200 degrees C.

7. The method of claim 1, wherein the contact angle of the layer comprising AZO is reduced by at least 10 degrees due to the ion beam treatment.

8. The method of claim 1, wherein the contact angle of the layer comprising AZO is reduced by at least 15 degrees due to the ion beam treatment.

9. The method of claim 1, wherein the contact angle of the layer comprising AZO is reduced by at least 20 degrees due to the ion beam treatment.

10. The method of claim 1, wherein the contact angle of the layer comprising AZO is reduced by at least 25 degrees due to the ion beam treatment.

11. The method of claim 1, wherein the contact angle of the layer comprising AZO is reduced by at least 30 degrees due to the ion beam treatment.

12. A method of making a front contact for a solar cell, the method comprising:
depositing a layer comprising a transparent conductive oxide (TCO) on a glass substrate;
ion beam treating the layer comprising the TCO with at least one ion source to reduce the contact angle of the layer comprising the TCO by at least about 10 degrees; and
etching the layer comprising a TCO with a weak acid in order to texture at least a surface of the TCO.

13. The method of claim 12, wherein the layer comprising the TCO comprises aluminum-doped zinc oxide (AZO).

14. The method of claim 12, further comprising:
disposing a dielectric coating over and contacting the glass substrate;
disposing an IR reflecting layer on the dielectric coating, under the TCO-based layer; and
disposing a semiconductor layer and/or layer stack on the textured surface of the TCO.

15. The method of claim 13, wherein the layer comprising AZO overcoats a silver-based transparent conductive coating.

16. The method of claim 13, wherein the layer comprising AZO has a post-etch thickness of from about 50 to 400 nm.

17. The method of claim 13, wherein the layer comprising AZO comprises from about 0.5 to 4% Al.

18. The method of claim 13, wherein the textured layer comprising AZO has peaks and valleys, wherein an average height measured from the bottom of a valley to the top of a peak is from about 50 to 3,000 nm.

19. The method of claim 18, wherein the average height is from about 100 to 1,000 nm.

20. The method of claim 12, wherein a voltage used to perform the ion beam treating is from about 1,000 to 7,000 V.

21. The method of claim 12, wherein the etching comprises etching with an acetic acid solution.

22. The method of claim 21, wherein the acetic acid solution is diluted.

23. The method of claim 12, wherein the etching comprises etching with an HCl solution.

24. The method of claim 12, wherein the weak acid has a pH of from about 2.5 to 4.5.

25. The method of claim 12, wherein a gas used during said ion beam treating comprises Ar.

26. The method of claim 25, wherein the gas used during the ion beam treating further comprises oxygen.

27. The method of claim 12, wherein the TCO layer is used as a front transparent electrode in a solar cell, and wherein after depositing, ion beam treating, and etching, the front transparent electrode is baked at a temperature of from about 50 to 400 degrees C.

28. The method of claim 27, wherein the front transparent electrode is baked for a period of from about 20 to 40 minutes.

29. The method of claim 13, wherein the AZO-based layer is monolithic, and has a post-etch thickness of from about 200 to 1,000 nm.

30. A front electrode for use in a photovoltaic device, the electrode comprising a sputter-deposited and ion beam-treated transparent conductive oxide layer comprising aluminum-doped zinc oxide (AZO), wherein the layer comprising AZO has a contact angle of no greater than about 65 degrees.
